(19) United States
(12) Patent Application Publication
(10) Pub. No.: US 2017/0194296 A1
(43) Pub. Date: Jul. 6, 2017

(54) SEMICONDUCTOR MODULE

(71) Applicant: KABUSHIKI KAISHA TOSHIBA, Tokyo (JP)

(72) Inventor: Katsuhiro YASUI, Komatsu Ishikawa (JP)

(21) Appl. No.: 15/231,444

(22) Filed: Aug. 8, 2016

(30) Foreign Application Priority Data
Jan. 4, 2016 (JP) 2016-000113

(51) Int. Cl. H01L 25/07; H01L 23/04; H01L 23/00; H01L 23/29; H01L 25/00

(52) U.S. Cl. CPC H01L 25/072; H01L 23/29; H01L 25/50; H01L 24/48; H01L 24/85; H01L 23/041

(57) ABSTRACT

A semiconductor module includes an insulating substrate. A first and a second metal member are joined respectively to a side surface of the substrate. Each metal member has an opening formed therein. A first and a second conductive layer are on the upper surface of the substrate and spaced apart from each other. A first semiconductor chip is mounted on the first conductive layer. A first electrode of the first semiconductor chip is electrically connected to the first conductive layer, and a second electrode is electrically connected to the second conductive layer. A first terminal is electrically connected to the first conductive layer, and a second terminal is electrically connected to the second conductive layer. A sealing resin is disposed on the upper surface of the substrate to cover the first conductive layer, the second conductive layer, the first semiconductor chip, and portions of the first and second terminals.

### CROSS-REFERENCE TO RELATED APPLICATION

This application is based upon and claims the benefit of priority from Japanese Patent Application No. 2016-000113, filed Jan. 4, 2016, the entire contents of which are incorporated herein by reference.

### FIELD

Embodiments of the present disclosure relate to a semiconductor module.

### BACKGROUND

There currently exists a semiconductor module in which a ceramic substrate is joined to a heat radiating board by soldering. A semiconductor chip is mounted on the ceramic substrate. In this type of semiconductor module, heat generated by the semiconductor chip is transported through the solder and the heat radiating board for removal.

In these semiconductor modules, a force is applied to the solder due to differences between the thermal expansion of the ceramic substrate and the heat radiating board. When the force applied to the solder is large, or when the force is repeatedly applied to the solder by thermal cycling, a crack may be formed in the solder, and the thermal conductivity of the solder will be reduced. As a result, the temperature of the semiconductor chip in the semiconductor module may rise, which may ultimately cause or promote breakdown of the semiconductor chip due to increased thermal effects.

### DESCRIPTION OF THE DRAWINGS

FIG. 1 is a top view showing a semiconductor module according to a first embodiment.

FIG. 2 is a cross-sectional view taken along the line A-A′ of FIG. 1.

FIG. 3 is a perspective view showing the semiconductor module according to the first embodiment.

FIG. 4 is a cross-sectional view showing a portion of a semiconductor module according to a reference example from the prior art.

FIG. 5 is a perspective view showing a semiconductor module according to a second embodiment.

### DETAILED DESCRIPTION

In general, according to one embodiment, a semiconductor module comprises an insulating substrate. A first metal member has an opening therein and is joined to a first side surface of the insulating substrate. A second metal member has an opening therein and is joined to a second side surface of the insulating substrate. A first conductive layer is on an upper surface of the insulating substrate. A second conductive layer is also on the upper surface of the insulating substrate and spaced apart from the first conductive layer. A first semiconductor chip is mounted on the first conductive layer. A first electrode of the first semiconductor chip is electrically connected to the first conductive layer, and a second electrode is electrically connected to the second conductive layer. A first terminal is electrically connected to the first conductive layer, and a second terminal electrically is connected to the second conductive layer. A sealing resin is disposed on the upper surface of the insulating substrate to cover the first conductive layer, the second conductive layer, the first semiconductor chip, a portion of the first terminal, and a portion of the second terminal.

Example embodiments of the present disclosure will be described below with reference to the accompanying drawings.

Note that the drawings are schematic or conceptual, and relationship between the thickness and width of each portion, and the size ratio between portions are not necessarily accurate. Further, even if the same portions are shown in different drawings, respective dimensions and ratios may be differently shown in different drawings.

In addition, the same reference numbers are assigned to the same elements as those already described in the specification and each drawing, and detailed description thereof is omitted as appropriate.

An XYZ orthogonality coordinate system is used for the description of the example embodiments. It is assumed that two directions parallel to the main surface of a substrate 1 are the X direction and the Y direction and are orthogonal to each other, and a direction orthogonal to both of these X and Y directions is the Z direction.

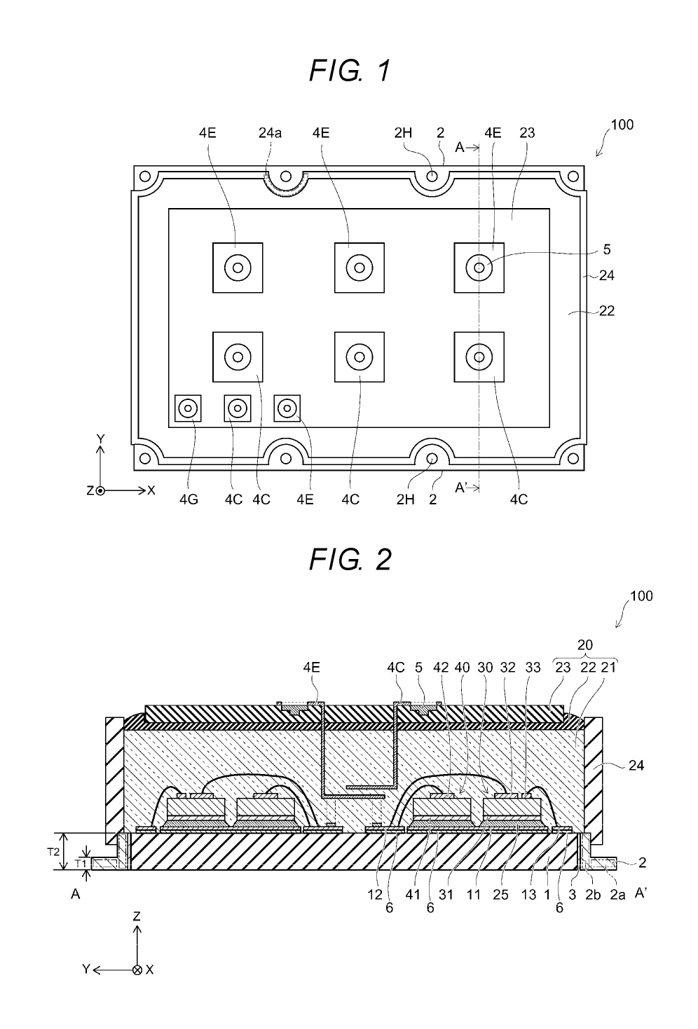

An example of a semiconductor module according to a first embodiment will be described with reference to FIGS. 1 to 3.

FIG. 1 is a top view showing a semiconductor module 100 according to the first embodiment.

FIG. 2 is a cross-sectional view taken along the line A-A′ of FIG. 1.

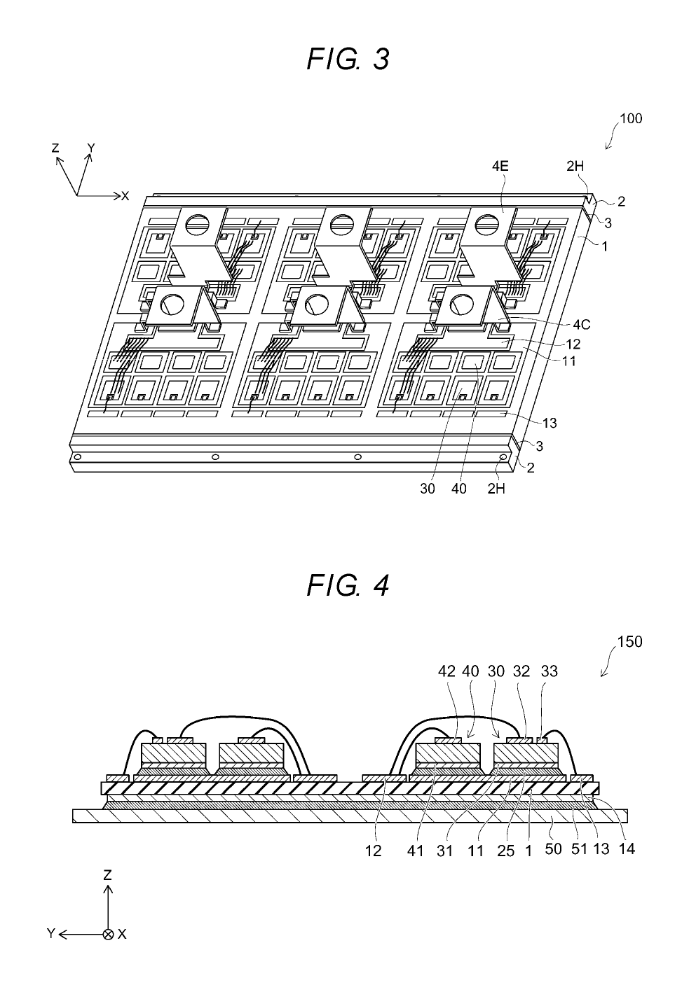

FIG. 3 is a perspective view showing the semiconductor module 100 according to the first embodiment.

Note that, in FIG. 3, a sealing portion 20, a case 24, some of terminals 4C, 4E, and 4G and the like are omitted from the depiction to better explain the internal structure of the semiconductor module 100. Further, in FIG. 3, a portion of a bonding wire connecting each electrode and each conductive layer is also omitted.

As shown in FIGS. 1 to 3, the semiconductor module 100 includes a substrate 1, a metal member 2, terminals 4C, 4E and 4G, a nut 5, a first conductive layer 11, a second conductive layer 12, a third conductive layer 13, a sealing portion 20, a case 24, a first semiconductor chip 30 and a second semiconductor chip 40.

In one example, the substrate 1 is an insulating ceramic substrate comprised of AlSiC (aluminum silicon carbide) or SiN (silicon nitride).

The metal member 2 extends in the X direction, and may be comprised of metal such as copper, aluminum or nickel. The metal member 2 is provided with a plurality of openings 2H that are arranged in the X direction.

As shown in FIG. 2, the substrate 1 is provided between a plurality of metal members 2. The substrate 1 and each of the metal members 2 are joined by brazing, and a joint portion 3 (first joint portion) comprised of a brazing material is provided between the substrate 1 and the metal member 2. The thickness T2 in the Z direction of a second portion 2b of the metal member 2, which is joined to the substrate 1, is larger than the thickness T1 in the Z direction of a first portion 2a in which the opening 2H is provided. Therefore, on the upper surface of the metal member 2, a step is formed between the first portion 2a and the second portion 2b. That is, there is a difference in height (Z-direction) for the upper surfaces of first portion 2a and second portion 2b.

A material having a melting point of 450° C. or higher may be used for the brazing material. Specific examples of such materials include, a silver brazing material, a copper brazing material, a brass brazing material, a palladium brazing material, a gold brazing material or a nickel brazing material may be used.

Note that the substrate 1 and the metal member 2 may instead be joined with a direct bonding method or the like, without using a brazing material.

A plurality of first conductive layers 11, a plurality of second conductive layers 12 and a plurality of third conductive layers 13 are provided on the substrate 1. These conductive layers are spaced apart from one another. Each of the conductive layers (11, 12, 13) and the substrate 1 are joined by brazing, and a joint portion 6 (second joint portion) comprised of a brazing material is provided between each of the conductive layers, and between the conductive layers and the substrate 1. The brazing material comprising the joint portion 6 may be the same as or different from the brazing material comprising the joint portion 3.

A plurality of first semiconductor chips 30 and a plurality of second semiconductor chips 40 can be provided on each of the first conductive layers 11. Each of the first semiconductor chips 30 and each of the second semiconductor chips 40 are joined to the first conductive layer 11 by solder 25.

As an example, the first semiconductor chip 30 may be an Insulated-Gate Bipolar Transistor (IGBT), and the second semiconductor chip 40 may be a diode. In this example, the first semiconductor chip 30 includes a collector electrode 31 (first electrode), an emitter electrode 32 (second electrode) and a gate electrode 33 (third electrode) . The second semiconductor chip 40 includes a cathode electrode 41 (fourth electrode) and an anode electrode 42 (fifth electrode). Here, the second semiconductor chip 40 is connected in reverse parallel to the first semiconductor chip 30. In other words, the second semiconductor chip 40 in this example functions as an FWD (Free Wheeling Diode).

The first conductive layer 11 is electrically connected to the collector electrode 31 and the cathode electrode 41. As depicted in FIG. 3, the collector electrode 31 and the cathode electrode are directly connected to the first conductive layer 11 by soldering (solder 25). The emitter electrode 32 and the anode electrode 42 are electrically connected to the second conductive layer 12 via a bonding wire. The gate electrode 33 is electrically connected to the third conductive layer 13 via a bonding wire. The gate electrode 33 is electrically isolated from the collector electrode 31 and the emitter electrode 32. In order to reduce the electrical resistance between each electrode and each conductive layer, more bonding wires than shown in FIG. 3 may be provided.

The first conductive layer 11 is electrically connected to the terminal 4C (first terminal). The second conductive layer 12 is electrically connected to the terminal 4E (second terminal). The third conductive layer 13 is electrically connected to the terminal 4G (third terminal) through wiring and/or a printed circuit board (not specifically depicted).

The case 24 is attached by an adhesive to the substrate 1 and the metal member 2 so as to surround the plurality of first semiconductor chips 30 and the plurality of second semiconductor chips 40. A portion of the lower end of the case 24 is in contact with the step between the first portion 2a and the second portion 2b of the metal member 2. That is, a portion of the lower end of the case 24 extends from above the upper surface of the second portion 2b towards the upper surface of the first portion 2a. The lower end of the case 24 as depicted in FIG. 2 contacts a side surface (a surface intersecting an X-Y plane) of second portion 2b, but does not reach the upper surface of the first portion 2a. As shown in FIG. 1, the case 24 includes a plurality of curved portions 24a positioned so that the case 24 and the openings 2H do not overlap when the semiconductor module 100 is viewed from the Z direction.

As shown in FIG. 2, the sealing portion 20 is provided on the substrate 1 and the metal member 2 in the case 24. A portion of each terminal 4C, 4E, and 4G, the first conductive layer 11, the second conductive layer 12, the third conductive layer 13, the first semiconductor chip 30 and the second semiconductor chip 40 are covered and sealed with the sealing portion 20. More specifically, the sealing portion 20 includes a first resin portion 21, a second resin portion 22 and a third resin portion 23, and components provided on the substrate 1 are sealed by the first resin portion 21.

The second resin portion 22 is provided on the first resin portion 21. At least a portion of the second resin portion 22 and the first resin portion 21 are provided in the case 24. The third resin portion 23 is further provided on the second resin portion 22, and a portion of terminals 4C, 4E, and 4G are exposed on the upper surface of the third resin portion 23. In the example shown in FIG. 2, the third resin portion 23 is provided only on a portion of the second resin portion 22. However, the area along the X-Y plane of the third resin portion 23 maybe larger than the example shown in FIG. 2, and, for example, the third resin portion 23 may cover the upper surface of the second resin portion 22 and the upper end of the case 24.

The first resin portion 21 is comprised of, for example, a silicone resin. The second resin portion 22 is comprised of, for example, an epoxy resin. The third resin portion 23 and the case 24 are comprised of, for example, polyphenylenesulfide, polybutylene terephthalate or nylon 9T.

As shown in FIG. 1, a portion of each of the terminals 4C, 4E and 4G is not covered with the sealing portion 20, and is exposed to the outside. An opening is formed in the exposed portion of each terminal. Further, a plurality of nuts 5 are provided on the upper surface of the third resin portion 23. These openings and nuts are configured so that a bus bar that would be connected to an external circuit can be inserted into each of the openings and mounted to each of the nuts 5.

Next, an example method of manufacturing the semiconductor module 100 will be described.

First, the substrate 1 and the metal member 2 in which a plurality of openings 2H are formed are prepared. Then, by brazing, a conductive layer is joined onto the entire upper surface of the substrate 1, and the metal member 2 is joined to the side surface of the substrate 1. Subsequently, a portion of the conductive layer arranged on the upper surface of the substrate 1 is removed, and a pattern is thus made into a prescribed shape to form conductive layers 11, 12, and 13.

On each of the conductive layers 11, the first semiconductor chip 30 and the second semiconductor chip 40 are mounted by solder. Then, wire bonding is performed to electrically connect each electrode on semiconductor chips 30 and 40 to one of the conductive layers 11, 12, and 13.

Next, the third resin portion 23 in which the terminals 4C, 4E, and 4G and the nuts 5 are incorporated is prepared. Subsequently, each of the terminals 4C, 4E, and 4G and each of the conductive layers 11, 12, and13 are joined by solder. Subsequently, using an adhesive including a silicone resin or the like, the case 24 is mounted on the substrate 1 and the metal member 2.

Next, silicone resin is injected into a space surrounded by the substrate 1, the third resin portion 23 and the case 24. The silicone resin is heated and cured to form the first resin portion 21. Then, epoxy resin is injected into the case 24 between the first resin portion 21 and the third resin portion 23. The epoxy resin is cured to form the second resin portion 22.

The semiconductor module 100 shown in FIGS. 1 to 3 may be manufactured by the above steps, according to one embodiment.

Alternatively, in the manufacturing method described above, after the case 24 is attached, the lower surface of the third resin portion 23 may be brought into contact with the upper end of the case 24, and the entire space surrounded by the substrate 1, the third resin portion 23 and the case 24 may be filled with the first resin portion 21. In this case, the first resin portion 21 is filled through openings formed in the third resin portion 23, and the openings are closed with another member such as a nut. Thus the sealing portion 20 is formed. When the semiconductor module 100 is manufactured with this process, the sealing portion 20 has only the first resin portion 21 and the third resin portion 23, and does not have the second resin portion 22.

Next, the operation and effect of the present embodiment will be described with reference to a semiconductor module according to a reference example.

FIG. 4 is a sectional view showing a portion of a semiconductor module 150 according to a reference example.

In the semiconductor module 150, a fourth conductive layer 14 is provided on the back surface of the substrate 1. The fourth conductive layer 14 is joined to a heat radiating board 50 by solder 51. A plurality of openings (not specifically depicted) is formed in the heat radiating board 50, like the openings 2H formed in the metal member 2.

Heat generated in the semiconductor chip is released from the heat radiating board 50 through the substrate 1 and the solder 51. In this configuration of the semiconductor module 150, each area of the substrate 1 and the heat radiating board 50 is large, and as such, a large force due to a difference between thermal expansion amounts of substrate 1 and heat radiating board 50 is applied to the solder 51. The load causes a crack in the solder 51, and the thermal conductivity of the solder 51 is reduced. As a result, the temperature of the semiconductor chip may rise, and the semiconductor chip may break due to the increased heat.

In contrast, according to the semiconductor module 100 of the embodiment depicted in FIG. 1-3, the metal member 2 may be joined by brazing to the side surface of the substrate 1, and the opening 2H formed in the metal member 2 may be used to mount the semiconductor module 100 to an external device. That is, there is no need to use the heat radiating board 50, and solder for joining the heat radiating board 50 and the substrate 1 for the semiconductor module 100. Therefore, with semiconductor module 100, it is possible to suppress breakdown of the semiconductor chip due to heat caused by the occurrence of a crack in solder.

Further, in the semiconductor module 100 according to the embodiment depicted in FIG. 1-3, the second portion 2b of the metal member 2, which is joined to the substrate 1, is thicker in the Z direction than the first portion 2a in which the opening 2H is provided. With a greater thickness of the second portion 2b in the Z direction compared to the thickness of the first portion 2a in the Z direction, the area where the substrate 1 and the metal member 2 are joined is greater, such that the strength of the joint between the substrate 1 and the metal member 2 is greater.

Further, because the second portion 2b is thicker than the first portion 2a in the Z direction, forming a step between the first portion 2a and the second portion 2b, it is possible to facilitate the positioning of the case 24 when the case 24 is mounted on the substrate 1 and the metal member 2.

Note that in addition to the embodiment described above with respect to FIG. 1-3, any number of the conductive layers and chips may be provided. Similarly, any shape of the conductive layers and terminals 4C, 4E, and 4G may be used. Further, in some embodiments only one of the first semiconductor chip 30 or second semiconductor chip 40 may be provided on the first conductive layer 11. Alternatively, instead of semiconductor chips incorporating an IGBT or diode, another semiconductor chip type maybe provided, such as MOSFET device. When only the second semiconductor chip 40 (which is a diode in the above examples) is provided on the first conductive layer 11, the semiconductor module 100 may not require the third conductive layer 13 and the terminal 4G. Additionally, the number and the shape of the openings 2H formed in the metal member 2 are not limited to the example shown in the drawings, and maybe changed as appropriate to requirements of mounting or specific materials incorporated in the semiconductor module 100.

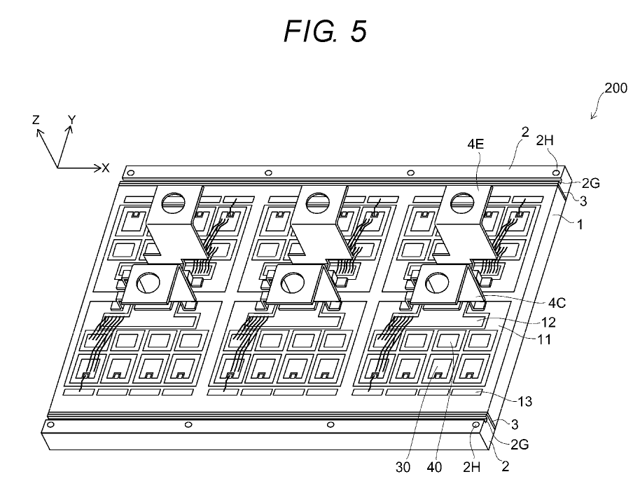

Further, instead of the structure shown in FIGS. 1 to 3, the metal member 2 may have a structure depicted in FIG. 5.

FIG. 5 is a perspective view showing a semiconductor module 200 according to a second embodiment.

In the semiconductor module 200, in addition to the openings 2H, a groove 2G is formed in the metal member 2. The lower end of the case 24 is brought into contact with the groove 2G. Thus, it is possible to facilitate the positioning of the case 24 when the case 24 is mounted on the substrate 1 and the metal member 2.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein may be made without departing from the spirit of the inventions. Those skilled in the known art may suitably select from known techniques, the specific configuration of each element included in the embodiment, such as a substrate, a metal member, a terminal, a nut, each conductive layer, a sealing portion, a case and a semiconductor chip. The accompanying claims and their equivalents are intended to cover such forms or modifications as would fall within the scope and spirit of the present disclosure. In addition, respective embodiments described above may be combined with one another.

What is claimed is:

1. A semiconductor module, comprising:
an insulating substrate;
a first metal member having an opening therein and joined to a first side surface of the insulating substrate;
a second metal member having an opening therein and joined to a second side surface of the insulating substrate;
a first conductive layer on an upper surface of the insulating substrate;
a second conductive layer on the upper surface of the insulating substrate and spaced apart from the first conductive layer;
a first semiconductor chip mounted on the first conductive layer, a first electrode of the first semiconductor chip being electrically connected to the first conductive layer, and a second electrode being electrically connected to the second conductive layer;
a first terminal electrically connected to the first conductive layer;
a second terminal electrically connected to the second conductive layer; and
a sealing resin disposed on the upper surface of the insulating substrate to cover the first conductive layer, the second conductive layer, the first semiconductor chip, a portion of the first terminal, and a portion of the second terminal.

2. The semiconductor module according to claim 1, wherein each of the first and second metal members includes:
a first portion having the opening therein and a first thickness that is less than a thickness of the insulating substrate, and
a second portion having a second thickness greater than the first thickness, the second portion being between the first portion and the insulating substrate and joined to the insulating substrate.

3. The semiconductor module according to claim 2, further comprising:
a joint portion between the second portion of first metal member and the insulating substrate, the joint portion being comprised of brazing material.

4. The semiconductor module according to claim 1, further comprising:
a third conductive layer on the upper surface of the insulating substrate and spaced apart from the first and second conductive layers; and
a third terminal electrically connected to the third conductive layer and including a portion covered by the sealing resin portion, wherein
the first semiconductor chip further includes a third electrode electrically connected to the third conductive layer.

5. The semiconductor module according to claim 4, further comprising:
a second semiconductor chip mounted on the first conductive layer, wherein
the first semiconductor chip includes an insulated-gate bipolar transistor, and
the second semiconductor chip includes a diode.

6. The semiconductor module according to claim 1, further comprising:
a case attached to the insulating substrate and the first and second metal members, the case including curved portions such that case does not cover openings in the first and second metal members, a lower end of the case contacting the second portions of the first and second metal members.

7. The semiconductor module according to claim 1, wherein the sealing resin portion comprises a first resin and a second resin that is different from the first resin.

8. A semiconductor module, comprising:
a ceramic substrate;
a first metal layer disposed on an upper surface of the ceramic substrate;
a second metal layer disposed on the upper surface of the ceramic substrate and spaced from the first metal layer;
a first semiconductor chip soldered to the first metal layer, a first electrode of the first semiconductor chip being electrically connected to the first metal layer, a second electrode of the first semiconductor chip being electrically connected to the second metal layer through a bonding wire;
a first metal member joined to a first side surface of the ceramic substrate by brazing material;
a second metal member joined to a second side surface of the ceramic substrate by brazing material;
a first resin material on the upper surface of the ceramic substrate and covering the first semiconductor chip, the first metal layer, and the second metal layer;
a first terminal electrically connected to the first metal layer and extending through the first resin material to an upper surface of the first resin material; and
a second terminal electrically connected to the second metal layer and extending through the first resin material to the upper surface of the first resin material, wherein
the first metal member comprises a first portion having a hole therein and a second portion between the first portion and the ceramic substrate.

9. The semiconductor module according to claim 8, wherein the first portion of the first metal member as thickness that is less than a thickness the second portion of the first metal member, and the thickness of the second portion is substantially equal to a maximum thickness of the ceramic substrate.

10. The semiconductor module according to claim 8, wherein a groove that is parallel to the first side surface of the ceramic substrate is formed in the second portion of the first metal member.

11. The semiconductor module according to claim 8, further comprising:
a third conductive layer on the upper surface of the ceramic substrate and spaced apart from the first conductive layer and the second conductive layer; and
a third terminal is electrically connected to the third conductive layer and extending through the first resin material to the upper surface of the first resin material;
wherein the first semiconductor chip further includes a third electrode, and
the third electrode is electrically connected to the third conductive layer.

12. The semiconductor module according to claim 11, further comprising:
a second semiconductor chip soldered to the first conductive layer, wherein
the first semiconductor chip is an insulated-gate bipolar transistor, and
the second semiconductor chip is a diode.

13. The semiconductor module according to claim 8, further comprising:
a case attached to the ceramic substrate and the first and second metal members, the case including curved portions such that case does not cover openings in the first and second metal members, a lower end of the case contacting the second portion of the first metal member.

14. The semiconductor module according to claim 13, wherein a groove that is parallel to the first side surface of the ceramic substrate is formed in the second portion of the first metal member, and the lower end of the case extends into the groove.

15. A method for producing a semiconductor module, comprising:
providing an insulating substrate having an upper surface with a first conductive layer thereon;
joining a first metal member to a first side surface of the insulating substrate, the first metal member having an opening extending through a first portion thereof;
joining a second metal member to a second side surface of the substrate, the second metal member having an opening extending through a first portion thereof; and
mounting a first semiconductor chip to the first conductive layer.

16. The method of claim 15, further comprising:
mounting a second semiconductor chip to the first conductive layer, wherein the first semiconductor chip is an insulated gate bipolar transistor and the second semiconductor chip is a diode.

17. The method of claim 15 further comprising:
attaching a case to the insulating substrate and first and second metal members with adhesive; and
covering the upper surface of the insulating substrate and the first semiconductor chip with a first resin material.

18. The method of claim 15, further comprising:
covering the upper surface of the insulating substrate and the first semiconductor chip with a sealing resin; and
electrically connecting an electrode of the first semiconductor chip to a terminal extending through the sealing resin to an upper surface of the sealing resin.

19. The method of claim 18, wherein the terminal is electrically connected to the electrode with a bonding wire.

20. The method of claim 15, wherein the terminal is joined to the first conductive layer.
